(19) United States
(12) Patent Application Publication
(10) Pub. No.: US 2010/0136477 A1
(43) Pub. Date: Jun. 3, 2010

(54) Photosensitive Composition

(76) Inventors: Edward W. Ng, Belle Mead, NJ (US); Nelson M. Felix, Ossining, NY (US); Munirathna Padmanaban, Bridgewater, NJ (US); Srinivasan Chakrapani, Bridgewater, NJ (US)

Correspondence Address: SANGYA JAIN;AZ ELECTRONIC MATERIALS USA CORP., 70 MEISTER AVENUE, SOMERVILLE, NJ, 08876, US

(21) Appl. No.: 12/325,627

(22) Filed: Dec. 1, 2008

(51) Int. Cl. G03F 7/004; G03F 7/20

(52) U.S. Cl. 430/270.1; 430/311

(57) ABSTRACT

The present invention relates to a novel photosensitive composition comprising a) an organic polymer, b) a photobase generator of structure (1), and c) optionally a photoacid generator,

(⁺A₁⁻O₂C)—B—(CO₂⁻A₂⁺)ₓ (1)

where A₁⁺ and A₂⁺ are independently an onium cation, x is an integer greater than or equal to 1, and B is a nonfluorinated hydrocarbon moiety. The photosensitive composition may be used as a photoresist composition or be used as an alkali developable antireflective underlayer coating composition.

### FIELD OF INVENTION

The present invention relates to a photosensitive composition and processes for forming fine patterns on a device.

### DESCRIPTION

Photosensitive compositions are used in microlithography processes for making miniaturized electronic components such as in the fabrication of computer chips and integrated circuits. Generally, in these processes, a thin coating of film of a photosensitive composition is first applied to a substrate material, such as silicon wafers used for making integrated circuits. The coated substrate is then baked to evaporate any solvent in the photosensitive composition and to fix the coating onto the substrate. The photosensitive composition may act as a photoresist or an antireflective coating. The photoresist layer is next subjected to an image-wise exposure to radiation and developed in an alkali developer to form an image in the photoresist. The photosensitive composition also may act as a developable antireflective underlayer coated beneath a photoresist, image-wise exposed and developed in an alkali developer to form an image in the photoresist and in the underlayer.

The radiation exposure causes a chemical transformation in the exposed areas of the photosensitive layer. Visible light, ultraviolet (UV) light, electron beam, extreme ultraviolet (euv) and X-ray radiant energy are radiation types commonly used today in microlithographic processes. After this image-wise exposure, the coated substrate is optionally baked, and then treated with a developer solution to dissolve and remove the radiation exposed composition.

Positive working photosensitive compositions when they are exposed image-wise to radiation have those areas of the photosensitive composition exposed to the radiation become more soluble to the developer solution while those areas not exposed remain relatively insoluble to the developer solution.

Photoresists sensitive to short wavelengths, between about 13 nm and about 300 nm, are often used where subhalfmicron geometries are required. Particularly preferred are deep uv photoresists sensitive at below 200 nm, e.g. 193 nm and 157 nm, comprising non-aromatic polymers, a photoacid generator, optionally a dissolution inhibitor, base quencher and solvent. High resolution, chemically amplified, deep ultraviolet (13-300 nm) positive tone photoresists are available for patterning images with less than quarter micron geometries.

Photoresists are also used to form narrow masked spaces on a substrate where the substrate is further etched to form trenches in the substrate. Hard mask patterning using positive photoresist has been found to give high resolution patterns over the substrate. However there is a need to provide for very narrow and deep trenches in the substrate using positive photoresists.

Chemically amplified compositions, in which a single photo generated proton catalytically cleaves several acid labile groups, are used in photolithography applicable to sub quarter-micron design rules. As a result of the catalytic reaction, the sensitivity of the resulting composition is quite high compared to the conventional novolak-DNQdiazonaphthoquinone photoresists. But chemically amplified compositions suffer from the so-called delay time effects. Photoresists based on a chemically amplified system comprise a polymer and a photoactive compound. The photoactive compound on exposure decomposes to form an acid. However, it is well known that the acid generated can diffuse from the exposed area to the unexposed area, hence causing a loss in image quality and resolution. Acid diffusion can result in changes in the dimensions of the imaged photoresist and in poor process latitude. Another issue is the loss of photogenerated acid on the surface of the latent image either due to evaporation of the acid or due to the reaction with the clean room amine contaminations contaminants. Acid loss on the surface leads to the formation of a severe surface insoluble layer in the exposed regions when there is a time delay between exposure and baking after exposure. Such problems of chemically amplified materials are well documented. For instance, the photoresist left after exposure in a clean room environment with an ammonia concentration of as low as 10 ppb, develops T-tops (an insoluble resist layer on the surface of the exposed areas) as well as changes in the critical dimension occur. The reasons for such shortcomings of chemically amplified photoresists are: (1) loss of acid or neutralization of the acid at the surface of the exposed areas of the resist by the base contaminants in the clean room atmosphere, and. (2) diffusion of acid from the exposed areas to the non-exposed areas between exposure and development steps. A basic additive can be used to prevent acid loss and acid diffusion.

Antireflective coatings based on a chemically amplified system which absorb the exposure radiation and are coated beneath a photoresist layer are useful to prevent reflection from the substrate. Such coatings, which are photosensitive and developable in an alkali developer, are also sensitive to the environment and require a basic additive.

The present invention relates to a novel photosensitive composition which comprises an organic polymer, a photobase generator and optionally a photoacid generator. The novel composition may be used as a photoresist comprising a photoacid generator and which composition is imaged and developed in an alkali soluble developer. The novel composition may also be used to form an absorbing antireflective underlayer coated under a layer of photoresist, imagewise exposed to radiation and developed in an alkali soluble developer to form an image in the photoresist and the underlayer.

### SUMMARY OF THE INVENTION

The present invention relates to a novel photosensitive composition comprising a) an organic polymer, b) a photobase generator of structure (1), and c) optionally a photoacid generator,

(⁺A₁⁻O₂C)—B—(CO₂⁻A₂⁺)ₓ (1)

where A₁⁺ and A₂⁺ are independently an onium cation, x is an integer greater than or equal to 1, and B is a nonfluorinated organic moiety. The photosensitive composition may be used as a photoresist composition or be used as an alkali developable antireflective underlayer coating composition.

### BRIEF DESCRIPTION OF THE DRAWINGS

FIG. 1 shows examples of the photobase generator.

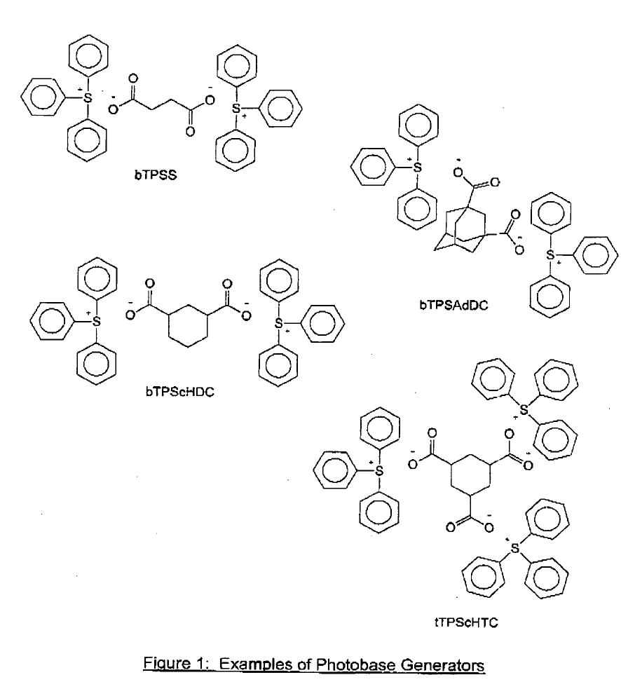

FIG. 2 shows examples of sulphonium ions.

FIG. 3 shows examples of photobase multianions.

### DETAILED DESCRIPTION OF THE INVENTION

The present invention relates to a novel photosensitive composition sensitive to exposure radiation comprising a) an organic polymer b) a photobase generator of structure (1), and c) optionally a photoacid generator. The invention also relates to processes for imaging the photosensitive composition.

The novel photosensitive composition comprises a) an organic polymer, b) a photobase generator of structure (1), and c) optionally a photoacid generator,

(⁺A₁⁻O₂C)—B—(CO₂⁻A₂⁺)ₓ (1)

where A₁⁺ and A₂⁺ are independently an onium cation, x is an integer greater than or equal to 1, and B is a nonfluorinated organic moiety. The photosensitive composition may be used as a photoresist composition or be used as an alkali developable antireflective underlayer coating composition.

In one embodiment of the novel invention, the photosensitive composition is used as a photoresist composition, where the composition comprises an alkali insoluble organic polymer which is transparent at the exposure radiation and comprises an acid labile group, a photoacid generator capable of forming a strong acid to cleave the acid labile group thus deprotecting the polymer after exposure, and a photobase generator of structure 1. Other components may be added to the composition.

In another embodiment of the photoresist composition, the composition may comprise an alkali soluble organic polymer which is transparent at the exposure radiation, a dissolution inhibitor comprising an acid cleavable bond, a photoacid generator capable of forming a strong acid to cleave a bond of the dissolution inhibitor and a photobase generator of structure 1. Other components may be added to the composition.

The novel photosensitive composition may also be used as an alkali developable bottom antireflective coating composition. In this embodiment the organic polymer comprises an absorbing chromophore group to absorb the exposure radiation reflected from the substrate. In one embodiment of the antireflective composition, the composition may comprise an alkali insoluble polymer comprising a chromophore and an acid labile group, an optional photoacid generator capable of forming a strong acid to cleave the acid cleavable group on the polymer after exposure, and a photobase generator of structure 1. In another embodiment of the antireflective composition, the composition may comprise an alkali soluble polymer comprising a chromophore, a dissolution inhibitor and/or crosslinker, an optional photoacid generator capable of forming a strong acid to cleave a bond of the dissolution inhibitor or crosslinker, and a photobase generator of structure 1. A photoacid generator capable of forming a strong acid to deprotect the polymer or cleaving the acid cleavable bond in the dissolution inhibitor or crosslinker may be present in the composition or may not be present. When the photoacid generator is not present in the novel composition, the cleavage of the acid cleavable bond in the novel composition may take place by the diffusion of the acid from a photoresist layer coated over the novel antireflective layer. Other components may be added to the composition, such as, crosslinking agents, thermal acid generators, surfactants, leveling agents and dyes.

The photobase generator is generally added to photosensitive compositions to improve resolution, improve linearity bias and to stabilize the latent image due to delay time between the exposure of the photosensitive composition and the subsequent post exposure baking which causes the acid based catalytic reaction of the exposed image in the composition. Acid diffusion after exposure can cause the regions of defined image to change. The presence of a base acts as a quencher to prevent diffusion of the acid and thus to improve resolution and linearity bias. The novel photobase generator of the present invention may be represented by the structure (1),

(⁺A₁⁻O₂C)—B—(CO₂⁻A₂⁺)ₓ (1)

where A₁⁺ and A₂⁺ are independently an onium cation, x is an integer greater than or equal to 1, and B is a nonfluorinated organic moiety. The multianion may be represented by (⁻O₂C)—B—(CO₂⁻)ₓ. The photobase generator is a compound that is absorbing at the exposure wavelength, and the photobase after exposure decomposes into inert products which do not greatly affect the lithographic process. In one embodiment of B, B may be free of sulfonyl (SO₃ or SO₃⁻) group. When x is greater than or equal to 1, the compound is bulky as compared to a monobasic compound and prevents diffusion of the photodecomposable base to the nonimaged regions in the photoresist and thus improves the resolution. B in the photobase generator can be selected from a moiety which is aromatic, aliphatic, heteroaromatic, heteroaliphatic and mixtures thereof.

The photobase generator is used as a quencher replacement of amine bases present in conventional formulations. When amine bases are used, the sensitivity of the photosensitive composition is decreased as a result of acid-base interactions with the photoacid generator in the formulation. The photobase generator of the present invention acts much like the amine base but does not affect the sensitivity of the formulation. As the exposed area is irradiated, the photobase generator releases its onium group and leaves weakly basic carbanions which neutralize the acid formed by the photoacid generator. The latent image is thus formed with better resolution than that of conventional formulations.

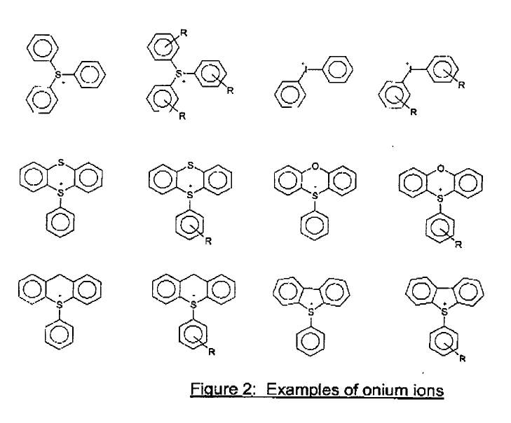

The onium cation may be selected from iodonium, sulfonium and ammonium cation. Preferred are sulfonium and iodonium cations. These cations may comprise at least one aromatic group. The aromatic group is absorbing at the exposure radiation. In one embodiment the onium cations may be represented by structures (2) and (3),

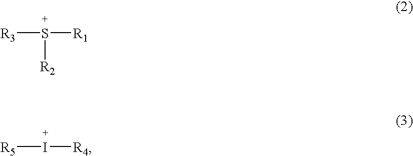

where R₁ to R₅ are independently selected from aliphatic groups, aromatic groups and mixtures thereof, R₂ and R₃ may be connected to form a cyclic group, and optionally further where at least one of R₁ to R₅ is an aromatic group. Any known onium cation may be used. The aliphatic group may be substituted or unsubstituted cyclic alkyl, substituted or unsubstituted linear alkyl, or substituted or unsubstituted branched alkyl group, and may further comprise hetero atoms. The aromatic group may be groups such as a substituted or unsubstituted phenyl, substituted or unsubstituted naphthyl or substituted or unsubstituted anthracyl, and may further comprise hetero atoms. Heteroaromatic groups comprising at least one nitrogen, sulfur or oxygen may be used. The substituents on the alkyl or aromatic group may be hydroxy, alkyl, ester, ether, etc. R₁ to R₅ may comprise an aliphatic moiety with a pendant aromatic group, such as alkylenecarbonylphenyl group. Examples of aromatic cations are where A₁⁺ and A₂⁺ are selected from triphenyl sulfonium, substituted triphenyl sulfonium, diphenyl iodonium, substituted diphenyl iodonium, phenyl thianthrenium, substituted phenyl thianthrenium, phenyl phenoxathiinium, substituted phenyl phenoxathiinium, phenyl thioxanthenium, substituted phenyl thioxanthenium, phenyl dibenzothiophenium, substituted phenyl dibenzothiophenium. Examples are further given in FIG. 2, where R is a substituent. The substituent, R, on the aromatic group may be exemplified by any C₁-C₂₀ alkyl such as methyl, ethyl, propyl, isopropyl, butyl, isobutyl, tert-butyl, pentyl, isopentyl, sec-pentyl, neopentyl, tert-pentyl, hexyl, heptyl, octyl, decyl, undecyl, dodecyl; halides such as chloro, bromo, fluoro; others such as cyano, nitro, alkylsulfonyl, fluoroalkylsulfonyl alkoxy and hydroxy. Other examples are substituted or unsubstituted cation of structure (4), where R₁ is as described above.

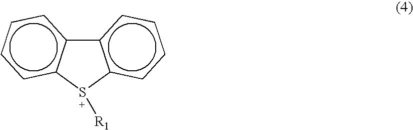

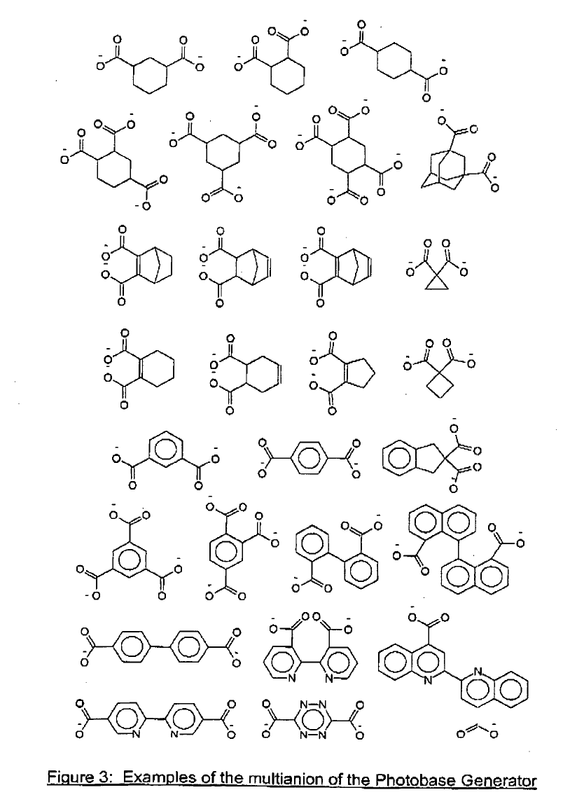

In the photobase generator, B is a nonfluorinated organic moiety, which is essentially hydrocarbon but may have some heteroatoms, like nitrogen, sulfur, oxygen, etc. B may be selected from nonfluorinated substituted aliphatic group, nonfluorinated unsubstituted aliphatic group, nonfluorinated substituted aromatic group, unsubstituted nonfluorinated aromatic group, and mixtures thereof. Examples of the nonfluorinated C₁-C₂₀ aliphatic group are linear, branched or cyclic alkylene, substituted cyclopropyl, unsubstituted cyclopropyl, substituted hexyl unsubstituted hexyl, substituted adamantyl, unsubstituted adamantyl etc. Examples of aromatic groups are phenyl, biphenyl, naphthyl, anthracyl, heteroaromatics and their substituted analogs. The substituents on the aliphatic or aromatic group may be any of those described previously. Examples of the group B are biphenyl, phenyl, naphthyl, binaphthyl, pyridyl, bipyridyl, quinolinyl, biquinolinyl, indanyl, triazinyl and tetrazinyl. Examples of the nonfluorinated C₁-C₂₀aliphatic group are methyl, ethyl, propyl, isopropyl, butyl, isobutyl, tert-butyl, pentyl, isopentyl, sec-pentyl, tert-pentyl, hexyl, heptyl, octyl, decyl, undecyl, dodecyl, cyclopropyl, cyclopentyl, cyclohexyl, cyclooctyl, cyclopentenyl cyclopentadienyl, cyclohexenyl, cyclohexadienyl, adamantyl, norbornyl and norbornenyl. The substituents on the alkylene or aromatic groups may be exemplified by such as methyl, ethyl, propyl, isopropyl, butyl, isobutyl, tert-butyl, pentyl, isopentyl, sec-pentyl, neopentyl, tert-pentyl, hexyl, heptyl, octyl, decyl, undecyl, dodecyl; halides such as chloro, bromo, fluoro; others such as cyano, nitro, alkylsulfonyl, fluoroalkylsulfonyl alkoxy and hydroxy. Examples of the multianion of the photobase generator are given in FIG. 3.

The photobase generator has a pKa in the range of about −3 to about 5, or about 1 to about 5. The value of x can range from about 2 to about 5 or about 2 to about 3. In one embodiment x is 1 or 2.

The photoacid generator is any known in the art and is capable of generating a strong acid upon irradiation. The pKa of the photoacid generator is in the range of about −12 to about −1, or about −12 to about −5. Suitable examples of the acid generating photosensitive compound include onium-salts, such as, diazonium salts, iodonium salts, sulfonium salts, halides and esters, although any photosensitive compound that produces an acid upon irradiation may be used. The onium salts are usually used in a form soluble in organic solvents, mostly as iodonium or sulfonium salts, examples of which are diphenyliodonium trifluoromethane sulfonate, diphenyliodonium nonafluorobutanesulfonate, triphenylsulfonium trifluromethanesuflonate, triphenylsulfonium nonafluorobutanesulfonate and triphenylsulfonium tris[(trifluoromethyl)sulfonyl]methane. Other compounds that form an acid upon irradiation may be used, such as triazines, oxazoles, oxadiazoles, thiazoles, substituted 2-pyrones. Phenolic sulfonic esters, bis-sulfonylmethanes, or bis-sulfonylmethanes, or bis-sulfonyldiazomethanes, are also preferred.

The organic polymer useful in the novel composition may be one which is alkali soluble or alkali insoluble. Any known polymer may be used. Polymers useful in the photosensitive compositions include those that have acid labile groups that make the polymer insoluble in aqueous alkaline solution, but such a polymer in the presence of an acid catalytically deprotects the polymer, wherein the polymer then becomes soluble in an aqueous alkaline solution. The polymers may be aromatic such as homopolymer or copolymers hydroxystyrene capped with an acid labile group. The alkali soluble organic polymer has a group capable of dissolving the polymer in an alkali developer.

In one embodiment of the novel composition when used as a photoresist, the alkali insoluble polymer preferably is transparent at the imagewise exposure wavelength and comprises an acid labile group capable of being cleaved in the presence of a strong acid. Such polymers which are sensitive below 200 nm and are essentially non-aromatic, are preferably acrylates and/or cycloolefin polymers. Such polymers are, for example, but not limited to, those described in U.S. Pat. No. 5,843,624, U.S. Pat. No. 5,879,857, WO 97/33198, U.S. Pat. No. 6,727,032 and U.S. Pat. No. 6,369,181. Nonaromatic polymers that are preferred for irradiation below 200 nm are substituted acrylates, cycloolefins, substituted polyethylenes, etc. Aromatic polymers based on polyhydroxystyrene and its copolymers may also be used, especially for 248 nm exposure.

Polymers based on acrylates are generally based on poly(meth)acrylates with at least one unit containing pendant alicyclic groups, and with the acid labile group being pendant from the polymer backbone and/or from the alicyclic group. Examples of pendant alicyclic groups, may be adamantyl, diamantyl, adamantyloxymethyl, tricyclodecyl, isobornyl, menthyl and their derivatives. Other pendant groups may also be incorporated into the polymer, such as mevalonic lactone, gamma butyrolactone, alkyloxyalkyl, etc. Examples of structures for the alicyclic group include:

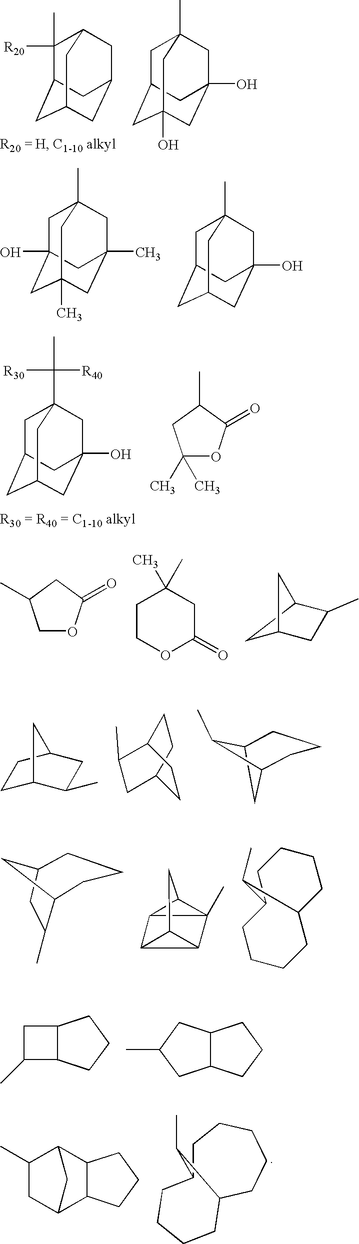

The type of monomers and their ratios incorporated into the polymer are optimized to give the best lithographic performance. Such polymers are described in R. R. Dammel et al., Advances in Resist Technology and Processing, SPIE, Vol. 3333, p 144, (1998). Examples of these polymers include poly(2-methyl-2-adamantyl methacrylate-co-mevalonic lactone methacrylate), poly(carboxy-tetracyclododecyl methacrylate-co-tetrahydropyranylcarboxytetracyclododecyl methacrylate), poly(tricyclodecylacrylate-co-tetrahydropyranyl methacrylate-co-methacrylicacid), poly(3-oxocyclohexyl methacrylate-co-adamantylmethacrylate).

Polymers synthesized from cycloolefins, with norbornene and tetracyclododecene derivatives, may be polymerized by ring-opening metathesis, free-radical polymerization or using metal organic catalysts. Cycloolefin derivatives may also be copolymerized with cyclic anhydrides or with maleimide or its derivatives. Examples of cyclic anhydrides are maleic anhydride (MA) and itaconic anhydride. The cycloolefin is incorporated into the backbone of the polymer and may be any substituted or unsubstituted multicyclic hydrocarbon containing an unsaturated bond. The monomer can have acid labile groups attached. The polymer may be synthesized from one or more cycloolefin monomers having an unsaturated bond. The cycloolefin monomers may be substituted or unsubstituted norbornene, or tetracyclododecane. The substituents on the cycloolefin may be aliphatic or cycloaliphatic alkyls, esters, acids, hydroxyl, nitrile or alkyl derivatives. Examples of cycloolefin monomers, without limitation, include:

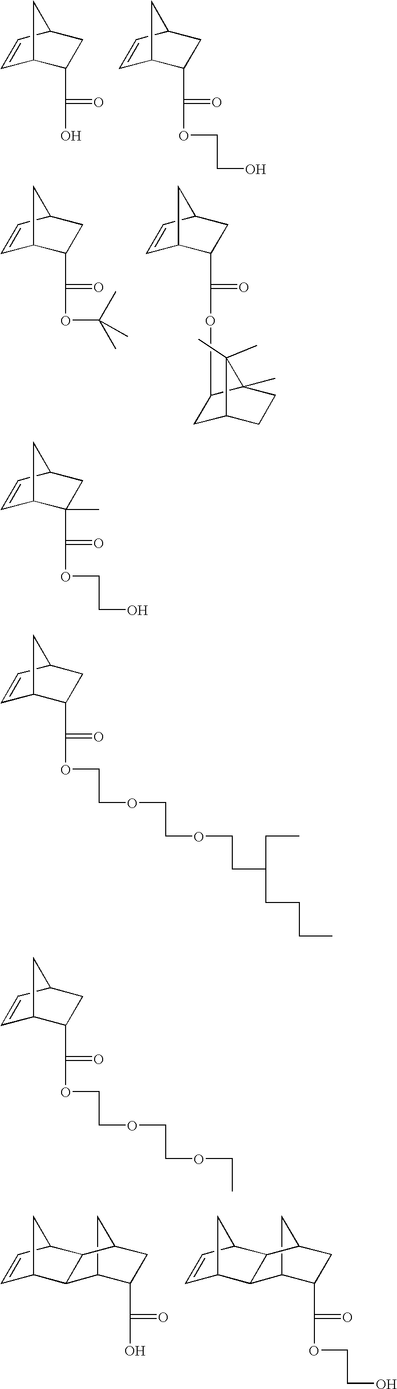

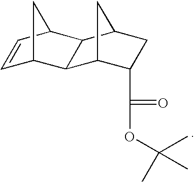

Other cycloolefin monomers which may also be used in synthesizing the polymer are:

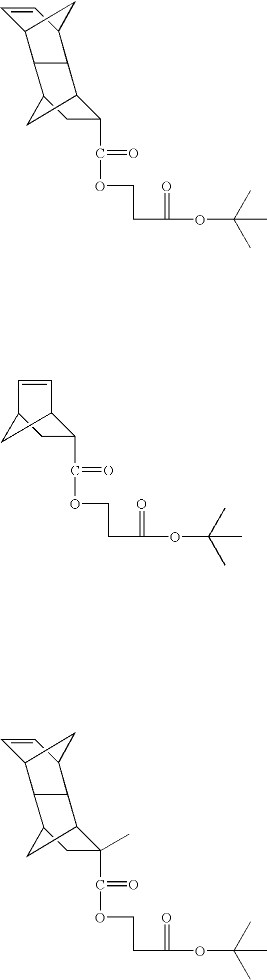

Such polymers are described in the following reference and incorporated herein, M-D. Rahman et al, Advances in Resist Technology and Processing, SPIE, Vol. 3678, p 1193, (1999). Examples of these polymers include poly((t-butyl-5-norbornene-2-carboxylate-co-2-hydroxyethyl-5-norbornene-2-carboxylate-co-5-norbornene-2-carboxylic acid-co-maleic anhydride), poly(t-butyl-5-norbornene-2-carboxylate-co-isobornyl-5-norbornene-2-carboxylate-co-2-hydroxyethyl-5-norbornene-2-carboxylate-co-5-norbornene-2-carboxylic acid-co-maleic anhydride), poly(tetracyclododecene-5-carboxylate-co-maleic anhydride), poly(t-butyl-5-norbornene-2-carboxylate-co-maleic anhydride-co-2-methyladamantyl methacrylate-co-2-mevalonic lactone methacrylate), poly(2-methyladamantyl methacrylate-co-2-mevalonic lactone methacylate) and the like.

Polymers containing mixtures of (meth)acrylate monomers, cycloolefinic monomers and cyclic anhydrides, where such monomers are described above, may also be combined into a hybrid polymer. Examples of cycloolefin monomers include those selected from t-butyl norbornene carboxylate (BNC), hydroxyethyl norbornene carboxylate (HNC), norbornene carboxylic acid (NC), t-butyltetracyclo[4.4.0.1.^{2,6}1.^{7,10}]dodec-8-ene-3-carboxylate, and t-butoxy carbonylmethyl tetracyclo[4.4.0.1.^{2,6}1.^{7,10}]dodec-8-ene-3-carboxylate. In some instances, preferred examples of cycloolefins include t-butyl norbornene carboxylate (BNC), hydroxyethyl norbornene carboxylate (HNC), and norbornene carboxylic acid (NC). Other examples of suitable polymers include those described in U.S. Pat. Nos. 6,610,465, 6,120,977, 6,136,504, 6,013,416, 5,985,522, 5,843,624, 5,693,453 and 4,491,628, which are incorporated herein by reference. Blends of one or more photoresist resins may be used. Standard synthetic methods are typically employed to make the various types of suitable polymers. Procedures or references to suitable standard procedures (e.g., free radical polymerization) can be found in the aforementioned documents.

The cycloolefin and the cyclic anhydride monomer are believed to form an alternating polymeric structure, and the amount of the (meth)acrylate monomer incorporated into the polymer can be varied to give the optimal lithographic properties. The percentage of the (meth)acrylate monomer relative to the cycloolefin/anhydride monomers within the polymer ranges from about 95 mole % to about 5 mole %, further ranging from about 75 mole % to about 25 mole %, and also further ranging from about 55 mole % to about 45 mole %.

Fluorinated non-phenolic polymers, useful for 157 nm exposure, also exhibit line edge roughness and can benefit from the use of the novel mixture of photoactive compounds described in the present invention. Such polymers are described in U.S. Pat. No. 7,276,323 and U.S. Pat. No. 7,217,495 and incorporated herein by reference. Example of one such polymer is poly(tetrafluoroethylene-co-norbornene-co-5-hexafluoroisopropanol-substituted 2-norbornene.

Polymers synthesized from cycloolefins and cyano containing ethylenic monomers are described in the U.S. Pat. No. 6,686,429, the contents of which are hereby incorporated herein by reference, may also be used.

The molecular weight of the polymers is optimized based on the type of chemistry used and on the lithographic performance desired. Typically, the weight average molecular weight is in the range of 3,000 to 30,000 and the polydispersity is in the range 1.1 to 5, preferably 1.5 to 2.5.

Examples of styrenic polymers useful at 248 nm as a photoresist organic polymer, and possibly EUV, include p-isopropoxystyrene-p-hydroxystyrene polymer; m-isopropoxystyrene-m- or p-hydroxystyrene polymer; p-tetrahydropyranyloxystyrene-p-hydroxystyrene polymer; m-tetrahydropyranyloxystyrene-m- or p-hydroxystyrene polymer; p-tert-butoxystyrene-p-hydroxystyrene polymer; m-tert-butoxystyrene-m- or p-hydroxystyrene polymer; p-trimethylsilyloxystyrene-p-hydroxystyrene polymer; m-trimethylsilyloxystyrene-m- or p-hydroxystyrene polymer; p-tert-butoxycarbonyloxystyrene-p-hydroxystyrene polymer; m-tert-butoxycarbonyloxystyrene-m- or p-hydroxystyrene polymer; p-methoxy-α-methylstyrene-p-hydroxy-α-methylstyrene polymer; m-methoxy-α-methylstyrene-m- or p-hydroxy-α-methylstyrene polymer; p-tert-butoxycarbonyloxystyrene-p-hydroxystyrene-methyl methacrylate polymer; m-tert-butoxycarbonyloxystyrene-m- or p-hydroxystyrene-methyl methacrylate polymer; p-tetrahydroxypyranyloxystyrene-p-hydroxystyrene-tert-butyl methacrylate polymer; m-tetrahydroxypyranyloxystyrene-m- or p-hydroxystyrene-tert-butyl methacrylate polymer; p-tert-butoxystyrene-p-hydroxystyrene-fumaronitrile polymer; m-tert-butoxystyrene-m- or p-hydroxystyrenefumaraonitrile polymer; p-trimethylsilyloxystyrene-p-hydroxystyrene-p-chlorostyrene polymer; m-trimethylsilyloxystyrene-m- or p-hydroxystyrene-p-chlorostyrene polymer; p-tert-butoxystyrene-p-hydroxystyrene-tertbutyl methacrylate polymer; m-tert-butoxystyrene-m- or p-hydroxystyrene-tert-butyl methacrylate polymer; p-tert-butoxystyrene-p-hydroxystyrene-acrylonitrile polymer; m-tert-butoxystyrene-m- or p-hydroxystyreneacrylonitrile polymer; p-tert-butoxystyrene-p-hydroxystyrene-tertbutyl-p-ethenylphenoxyacetate polymer; m-tert-butoxystyrene-m- or p-hydroxystyrene-tert-butyl p-ethenylphenoxyacetate polymer; poly[p-(1-ethoxyethoxy)styrene-co-p-hydroxystyrene], poly-(p-hydroxystyrene-p-t-butoxycarbonyloxystyrene) etc.

In another embodiment of the novel composition when used as a photoresist, the alkali soluble organic polymer may be one containing a group which provides the alkaline solubility such as a phenolic for 248 nm exposure or a fluoroalcohol group for exposure below 200 nm. Homopolymers or copolymers of 4-hydroxystyrene, 4-hydroxy-3-methylstyrene, 4-hydroxy-3,5-dimethylstyrene may be used. The dissolution inhibitors are any that comprise a C—O—C or C—N—C bond which is capable of being cleaved by a strong acid. Examples of such polymers and dissolution inhibitors are U.S. Pat. Nos. 5,525,453 and 5,843,319 and incorporated herein by reference.

In another embodiment of the novel composition when used as an antireflective coating composition the polymer may be selected from the polymers described above and further comprise an absorbing chromophore group which absorbs radiation used for imagewise exposure. Chromophore groups are groups that absorb the exposure radiation. Polymers comprising at least one aromatic chromophore are useful for exposure below 200 nm. Examples of chromophore are aromatic groups such as groups comprising phenyl, naphthyl or anthracyl which may be further substituted. The polymers described above may further comprise the aromatic group in the backbone of the polymer or be pendant from the backbone of the polymer. Examples of absorbing monomers are hydroxystyrene, styrene, alkylated hydroxystyrene, alkylated styrene. Examples of absorbing polymers are described in U.S. Pat. Nos. 6,844,131, 6,054,274 and US 2003/0215736 and incorporated herein. The absorbing polymer may have an aromatic group with a pendant acid labile group, such as a t-butoxycarbonyloxystyrene. The above described styrenic polymers are also especially useful as the organic polymer for alkali developable antireflective coatings for exposure below 200 nm.

A variety of crosslinking agents can be used in some embodiments of the composition of the present invention, especially for antireflective coating compositions. Any suitable crosslinking agents that can crosslink the polymer in the presence of an acid may be used. The polymer may be an alkali insoluble polymer comprising an acid labile group, a chromophore group and a group capable of crosslinking with a crosslinker such as a hydroxy group, methylol etc. Polymers comprising acid labile groups have been described herein. Chromophore groups are groups that absorb the exposure radiation. Examples of chromophore are aromatic groups such as groups comprising, phenyl, naphthyl or anthracyl which may be further substituted. The antireflective coating composition can comprise a polymer which is an alkali soluble polymer with a chromophore and a group capable of crosslinking with a crosslinker such as a hydroxy group, a dissolution inhibitor, a crosslinker and optionally a photoacid generator, as described herein. Examples of crosslinkers are, without limitation, of such crosslinking agents are resins containing melamines, methylols, glycoluril, polymeric glycolurils, benzoguanamine, urea, hydroxy alkyl amides, epoxy and epoxy amine resins, blocked isocyanates, and divinyl monomers. Monomeric melamines like hexamethoxymethyl melamine; glycolurils like tetrakis(methoxymethyl)glycoluril; and aromatic methylols, like 2,6 bishydroxymethyl p-cresol may be used. Crosslinking agents disclosed in US 2006/0058468 and incorporated herein by reference, where the crosslinking agent is a polymer obtained by reacting at least one glycoluril compound with at least one reactive compound containing at least one hydroxy group and/or at least one acid group may be used.

The novel composition comprising the organic polymer, the photobase generator, optionally a photoacid generator, and the crosslinker, may further comprise a thermal acid generator. The thermal acid generator is capable of generating a strong acid upon heating. The thermal acid generator (TAG) used in the present invention may be any one or more that upon heating generates an acid which can react with the polymer and propagate crosslinking of the polymer present in the invention, particularly preferred is a strong acid such as a sulfonic acid. Preferably, the thermal acid generator is activated at above 90° C. and more preferably at above 120° C., and even more preferably at above 150° C. Examples of thermal acid generators are metal-free sulfonium salts and iodonium salts, such as triarylsulfonium, dialkylarylsulfonium, and diarylakylsulfonium salts of strong non-nucleophilic acids, alkylaryliodonium, diaryliodonium salts of strong non-nucleophilic acids; and ammonium, alkylammonium, dialkylammonium, trialkylammonium, tetraalkylammonium salts of strong non nucleophilic acids. Also, covalent thermal acid generators are also envisaged as useful additives for instance 2-nitrobenzyl esters of alkyl or arylsulfonic acids and other esters of sulfonic acid which thermally decompose to give free sulfonic acids. Examples are diaryliodonium perfluoroalkylsulfonates, diaryliodonium tris(fluoroalkylsulfonyl)methide, diaryliodonium bis(fluoroalkylsulfonyl)methide, diaryliodonium bis(fluoroalkylsulfonyl)imide, diaryliodonium quaternary ammonium perfluoroalkylsulfonate. Examples of labile esters: 2-nitrobenzyl tosylate, 2,4-dinitrobenzyl tosylate, 2,6-dinitrobenzyl tosylate, 4-nitrobenzyl tosylate; benzenesulfonates such as 2-trifluoromethyl-6-nitrobenzyl 4-chlorobenzenesulfonate, 2-trifluoromethyl-6-nitrobenzyl 4-nitro benzenesulfonate; phenolic sulfonate esters such as phenyl, 4-methoxybenzenesulfonate; quaternary ammonium tris(fluoroalkylsulfonyl)methide, and quaternaryalkyl ammonium bis(fluoroalkylsulfonyl)imide, alkyl ammonium salts of organic acids, such as triethylammonium salt of 10-camphorsulfonic acid. A variety of aromatic (anthracene, naphthalene or benzene derivatives) sulfonic acid amine salts can be employed as the TAG, including those disclosed in U.S. Pat. Nos. 3,474,054, 4,200,729, 4,251,665 and 5,187,019. Preferably the TAG will have a very low volatility at temperatures between 170-220° C. Examples of TAGs are those sold by King Industries under Nacure and CDX names. Such TAG's are Nacure 5225, and CDX-2168E, which is a dodecylbenzene sulfonic acid amine salt supplied at 25-30% activity in propylene glycol methyl ether from King Industries, Norwalk, Conn. 06852, USA.

The solid components of the present invention are dissolved in an organic solvent. The amount of solids in the solvent or mixture of solvents ranges from about 1 weight % to about 50 weight %. The polymer may be in the range of 5 weight % to 90 weight % of the solids and the optional photoacid generator may be in the range of 1 weight % to about 50 weight % of the solids. The photobase generator may be in the range of about 2 weight % to about 8 weight %. Suitable solvents for such photoresists may include for example ketones such as acetone, methyl ethyl ketone, methyl isobutyl ketone, cyclohexanone, isophorone, methyl isoamyl ketone, 2-heptanone 4-hydroxy, and 4-methyl 2-pentanone; C₁ to C₁₀ aliphatic alcohols such as methanol, ethanol, and propanol, aromatic group containing-alcohols such as benzyl alcohol; cyclic carbonates such as ethylene carbonate and propylene carbonate; aliphatic or aromatic hydrocarbons (for example, hexane, toluene, xylene, etc and the like); cyclic ethers, such as dioxane and tetrahydrofuran; ethylene glycol; propylene glycol; hexylene glycol; ethylene glycol monoalkylethers such as ethylene glycol monomethylether, ethylene glycol monoethylether; ethylene glycol alkylether acetates such as methylcellosolve acetate and ethylcellosolve acetate, ethylene glycol dialkylethers such as ethylene glycol dimethylether, ethylene glycol diethylether, ethylene glycol methylethylether, diethylene glycol monoalkylethers such as diethylene glycol monomethylether, diethylene glycol monoethylether, and diethylene glycol dimethylether; propylene glycol monoalkylethers such as propylene glycol methylether (PGME), propylene glycol ethylether, propylene glycol propylether, and propylene glycol butylether; propylene glycol alkyletheracetates such as propylene glycol methylether acetate (PGMEA), propylene glycol ethylether acetate, propylene glycol propylether acetate, and propylene glycol butylether acetate; propylene glycol alkyletherpropionates such as propylene glycol methyletherpropionate, propylene glycol ethyletherpropionate, propylene glycol propyletherproponate, and propylene glycol butyletherpropionate; 2-methoxyethyl ether (diglyme); solvents that have both ether and hydroxy moieties such as methoxy butanol, ethoxy butanol, methoxy propanol, and ethoxy propanol; esters such as methyl acetate, ethyl acetate, propyl acetate, and butyl acetate methyl-pyruvate, ethyl pyruvate; ethyl 2-hydroxy propionate, methyl 2-hydroxy 2-methyl propionate, ethyl 2-hydroxy 2-methyl propionate, methyl hydroxy acetate, ethyl hydroxy acetate, butyl hydroxy acetate, methyl lactate, ethyl lactate, propyl lactate, butyl lactate, methyl 3-hydroxy propionate, ethyl 3-hydroxy propionate, propyl 3-hydroxy propionate, butyl 3-hydroxy propionate, methyl 2-hydroxy 3-methyl butanoic acid, methyl methoxy acetate, ethyl methoxy acetate, propyl methoxy acetate, butyl methoxy acetate, methyl ethoxy acetate, ethyl ethoxy acetate, propyl ethoxy acetate, butyl ethoxy acetate, methyl propoxy acetate, ethyl propoxy acetate, propyl propoxy acetate, butyl propoxy acetate, methyl butoxy acetate, ethyl butoxy acetate, propyl butoxy acetate, butyl butoxy acetate, methyl 2-methoxy propionate, ethyl 2-methoxy propionate, propyl 2-methoxy propionate, butyl 2-methoxy propionate, methyl 2-ethoxypropionate, ethyl 2-ethoxypropionate, propyl 2-ethoxypropionate, butyl 2-ethoxypropionate, methyl 2-butoxypropionate, ethyl 2-butoxypropionate, propyl 2-butoxypropionate, butyl 2-butoxypropionate, methyl 3-methoxypropionate, ethyl 3-methoxypropionate, propyl 3-methoxypropionate, butyl 3-methoxypropionate, methyl 3-ethoxypropionate, ethyl 3-ethoxypropionate, propyl 3-ethoxypropionate, butyl 3-ethoxypropionate, methyl 3-propoxypropionate, ethyl 3-propoxypropionate, propyl 3-propoxypropionate, butyl 3-propoxypropionate, methyl 3-butoxypropionate, ethyl 3-butoxypropionate, propyl 3-butoxypropionate and butyl 3-butoxypropionate; oxyisobutyric acid esters, for example, methyl-2-hydroxyisobutyrate, methyl α-methoxyisobutyrate, ethyl methoxyisobutyrate, methyl α-ethoxyisobutyrate, ethyl α-ethoxyisobutyrate, methyl β-methoxyisobutyrate, ethyl β-methoxyisobutyrate, methyl β-ethoxyisobutyrate, ethyl β-ethoxyisobutyrate, methyl β-isopropoxyisobutyrate, ethyl β-isopropoxyisobutyrate, isopropyl β-isopropoxyisobutyrate, butyl β-isopropoxyisobutyrate, methyl β-butoxyisobutyrate, ethyl β-butoxyisobutyrate, butyl β-butoxyisobutyrate, methyl α-hydroxyisobutyrate, ethyl α-hydroxyisobutyrate, isopropyl α-hydroxyisobutyrate, and butyl α-hydroxyisobutyrate; solvents that have both ether and hydroxy moieties such as methoxy butanol, ethoxy butanol, methoxy propanol, and ethoxy propanol; and other solvents such as dibasic esters, and gamma-butyrolactone; a ketone ether derivative such as diacetone alcohol methyl ether; a ketone alcohol derivative such as acetol or diacetone alcohol; lactones such as butyrolactone; an amide derivative such as dimethylacetamide or dimethylformamide, anisole, and mixtures thereof.

Various other additives such as colorants, non-actinic dyes, anti-striation agents, plasticizers, adhesion promoters, dissolution inhibitors, coating aids, photospeed enhancers, additional photoacid generators, and solubility enhancers (for example, certain small levels of solvents not used as part of the main solvent (examples of which include glycol ethers and glycol ether acetates, valerolactone, ketones, lactones, and the like), and surfactants may be added to the photoresist composition before the solution is coated onto a substrate. Surfactants that improve film thickness uniformity, such as fluorinated surfactants, can be added to the photoresist solution. A sensitizer that transfers energy from a particular range of wavelengths to a different exposure wavelength may also be added to the photoresist composition. Often bases are also added to the photoresist to prevent t-tops or bridging at the surface of the photoresist image. Examples of bases are amines, ammonium hydroxide, and photosensitive bases. Particularly preferred bases are trioctylamine, diethanolamine and tetrabutylammonium hydroxide.

The prepared novel photoresist composition solution can be applied to a substrate by any conventional method used in the photoresist art, including dipping, spraying, and spin coating. When spin coating, for example, the photoresist solution can be adjusted with respect to the percentage of solids content, in order to provide coating of the desired thickness, given the type of spinning equipment utilized and the amount of time allowed for the spinning process. Suitable substrates include silicon, aluminum, polymeric resins, silicon dioxide, doped silicon dioxide, silicon nitride, tantalum, copper, polysilicon, ceramics, aluminum/copper mixtures; gallium arsenide and other such Group III/V compounds. The photoresist may also be coated over antireflective coatings. The photoresist coatings produced by the described procedure are particularly suitable for application to silicon/silicon dioxide wafers, such as are utilized in the production of microprocessors and other miniaturized integrated circuit components. An aluminum/aluminum oxide wafer can also be used. The substrate may also comprise various polymeric resins, especially transparent polymers such as polyesters.

The photoresist composition solution is then coated onto the substrate, and the substrate is treated (baked) at a temperature from about 70° C. to about 150° C. for from about 30 seconds to about 180 seconds on a hot plate or for from about 15 to about 90 minutes in a convection oven. This temperature treatment is selected in order to reduce the concentration of residual solvents in the photoresist, while not causing substantial thermal degradation of the solid components. In general, one desires to minimize the concentration of solvents and this first temperature. Treatment (baking) is conducted until substantially all of the solvents have evaporated and a thin coating of photoresist composition, on the order of half a micron (micrometer) in thickness, remains on the substrate. In a preferred embodiment the temperature is from about 95° C. to about 120° C. The treatment is conducted until the rate of change of solvent removal becomes relatively insignificant. The film thickness, temperature and time selection depends on the photoresist properties desired by the user, as well as the equipment used and commercially desired coating times. The coated substrate can then be imagewise exposed to actinic radiation, e.g., ultraviolet radiation, at a wavelength of from about 10 nm (nanometers) to about 300 nm, x-ray, electron beam, ion beam or laser radiation, in any desired pattern, produced by use of suitable masks, negatives, stencils, templates, etc.

The photoresist is then subjected to a post exposure second baking or heat treatment before development. The heating temperatures may range from about 90° C. to about 150° C., more preferably from about 100° C. to about 130° C. The heating may be conducted for from about 30 seconds to about 2 minutes, more preferably from about 60 seconds to about 90 seconds on a hot plate or about 30 to about 45 minutes by convection oven.

The exposed photoresist-coated substrates are developed to remove the image-wise exposed areas by immersion in a developing solution or developed by spray development process. The solution is preferably agitated, for example, by nitrogen burst agitation. The substrates are allowed to remain in the developer until all, or substantially all, of the photoresist coating has dissolved from the exposed areas. Developers include aqueous solutions of ammonium or alkali metal hydroxides. One preferred developer is an aqueous solution of tetramethyl ammonium hydroxide. After removal of the coated wafers from the developing solution, one may conduct an optional post-development heat treatment or bake to increase the coating's adhesion and chemical resistance to etching conditions and other substances. The post-development heat treatment can comprise the oven baking of the coating and substrate below the coating's softening point or UV hardening process. In industrial applications, particularly in the manufacture of microcircuitry units on silicon/silicon dioxide-type substrates, the developed substrates may be treated with a buffered, hydrofluoric acid base etching solution or dry etching. Prior to dry etching the photoresist may be treated to electron beam curing in order to increase the dry-etch resistance of the photoresist.

The invention further provides a method for producing a semiconductor device by producing a photo-image on a substrate by coating a suitable substrate with a photoresist composition. The subject process comprises coating a suitable substrate with a photoresist composition and heat treating the coated substrate until substantially all of the photoresist solvent is removed; image-wise exposing the composition and removing the image-wise exposed areas of such composition with a suitable developer.

The novel photosensitive composition may be used as an antireflective underlayer composition. The antireflective coating composition is coated on the substrate using techniques well known to those skilled in the art, such as dipping, spin coating or spraying. Various substrates known in the art, as described herein may be used, and may be planar, have topography or have holes. The coating is heated to essentially remove the coating solvent. The preferred range of temperature is from about 40° C. to about 240° C., more preferably from about 80° C. to about 150° C. The film thickness of the antireflective coating ranges from about 20 nm to about 1000 nm. The optimum film thickness is determined, as is well known in the art, to be where good lithographic properties are obtained, especially where no standing waves are observed in the photoresist. The antireflective coating is also insoluble at this stage in the alkaline developing solution. The absorption parameter (k) of the novel composition ranges from about 0.1 to about 1.0, preferably from about 0.15 to about 0.7 as measured using ellipsometry. The refractive index (n) of the antireflective coating is also optimized. The exact values of the optimum ranges for k and n are dependent on the exposure wavelength used and the type of application. Typically for 193 nm the preferred range for k is 0.2 to 0.75, for 248 nm the preferred range for k is 0.25 to 0.8, and for 365 nm the preferred range is from 0.2 to 0.8. The thickness of the antireflective coating is less than the thickness of the top photoresist. Preferably the film thickness of the antireflective coating is less than the value of (wavelength of exposure/refractive index), and more preferably it is less than the value of (wavelength of exposure/2 times refractive index), where the refractive index is that of the antireflective coating and can be measured with an ellipsometer. The optimum film thickness of the antireflective coating is determined by the exposure wavelength, refractive indices of the antireflective coating and of the photoresist, and absorption characteristics of the top and bottom coatings. Since the bottom antireflective coating must be removed by exposure and development steps, the optimum film thickness is determined by avoiding the optical nodes where no light absorption is present in the antireflective coating. Any positive photoresist may be coated over the underlayer. A film of photoresist is then coated on top of the antireflective coating and baked to substantially remove the photoresist solvent. The photoresist and the antireflective coating bilevel system is then imagewise exposed. In a subsequent heating step the acid generated during exposure either reacts to deprotect the polymer or to break the acid cleavable bond in the dissolution inhibitor, and thus render the exposed regions alkali soluble in the developing solution. The temperature for the postexposure bake step can range from 40° C. to 200° C., preferably from 80° C. to 160° C. In some instances, it is possible to avoid the postexposure bake, since for certain chemistries, such as acetal acid labile groups, deprotection proceeds at room temperature. The bilevel system is then developed in an aqueous developer to remove the treated photoresist and the antireflective coating. The developer is preferably an aqueous alkaline solution comprising, for example, tetramethyl ammonium hydroxide. The developer may further comprise additives, such as surfactants, polymers, isopropanol, ethanol, etc. The photoresist and the antireflective coating may be removed in the alkali developer in a single development step. The process of coating and imaging photoresist coatings and antireflective coatings is well known to those skilled in the art and is optimized for the specific type of photoresist and antireflective coating combination used. The imaged bilevel system can then be processed further as required by the manufacturing process of integrated circuits, for example metal deposition and etching.

Each of the US documents referred to above are incorporated herein by reference in its entirety, for all purposes. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### EXAMPLES

### Synthesis Example 1

### Synthesis of Bis-Triphenylsulfonium succinate

### bTPSS

Silver (I) oxide (2.43 g) was added to a solution of triphenylsulfonium bromide (3.43 g) in methanol (50 mL) and stirred overnight at room temperature. The mixture was filtered to remove the solids and the filtrate was treated with succinic acid (0.59 g) and stirred for 2 hours. The mixture was concentrated in vacuo and the residue washed with diethyl ether (60 mL) four times. The product formed was a yellow solid and was dried in vacuo to give 3.26 g with 99% yield. Results: HPLC purity: 97%. ¹H NMR (CDCl₃, δ): 2.28 (s, 4H), 7.44-7.65 (m, 30H).

### Synthesis Example 2

### Synthesis of bis-Triphenylsulfonium adamantane-1,3-dicarboxylate

### bTPSAdDC

Silver (I) oxide (2.43 g) was added to a solution of triphenylsulfonium bromide (3.43 g) in methanol (100 mL) and stirred overnight at room temperature. The mixture was filtered to remove the solids and the filtrate was treated with adamantane-1,3-dicarboxylic acid (1.12 g) and stirred for 2 hours. The mixture was concentrated in vacuo and the residue washed with diethyl ether (25 mL) four times. The product formed was a beige solid was dried in vacuo to give 3.84 g, with about 100% yield. Results: HPLC purity: >99%. ¹H NMR (CDCl₃, δ): 1.30-1.86 (m, 14H), 7.50-7.74 (m, 30H).

### Synthesis Example 3

### Synthesis of Triphenylsulfonium cyclohexanecarboxylate

### TPScHC

Silver (I) oxide (2.55 g) was added to a solution of triphenylsulfonium bromide (3.42 g) in methanol (100 mL) and stirred overnight at room temperature. The mixture was filtered to remove the solids and the filtrate was treated with cyclohexanecarboxylic acid (1.28 g) and stirred for 2 hours. The mixture was concentrated in vacuo and the residue washed with diethyl ether (25 mL) four times. The product was a yellow solid and was dried in vacuo to give 3.88 g with a 99% yield. Results: HPLC purity: >99%. ¹H NMR (CDCl₃, δ): 0.92 (quint, 3H), 1.09 (q, 2H), 1.38 (m, 3H), 1.59 (d, 2H), 1.87 (dt, 1H), 7.45-7.63 (m, 15H).

### Synthesis Example 4

### Synthesis of Bis-Triphenylsulfonium cyclohexane-1,3-dicarboxylate

### bTPScHDC

Silver (I) oxide (4.05 g) was added to a solution of triphenylsulfonium bromide (5.28 g) in methanol (70 mL) and stirred overnight at room temperature. The mixture was filtered to remove the solids and the filtrate was treated with 1,3-cyclohexanedicarboxylic acid (1.20 g) and stirred for 2 hours. The mixture was concentrated in vacuo and the residue washed with diethyl ether (25 mL) four times. The product was yellow caramel was dried in vacuo to give 5.53 g, with about 100% yield. Results: HPLC purity: 98.5%. ¹H NMR (CDCl₃, δ) 1.00-2.40 (m, 10H), 7.68 (m, 18H), 7.78 (m, 12H).

### Synthesis Example 5

### Synthesis of Tris-Triphenylsulfonium cyclohexane-1,3,5-tricarboxylate

### tTPScHTC

Silver (I) oxide (4.05 g) was added to a solution of triphenylsulfonium bromide (5.66 g) in methanol (50 mL) and stirred overnight at room temperature. The mixture was filtered to remove the solids and the filtrate was treated with 1,3,5-cyclohexanetricarboxylic acid (1.08 g) and stirred for 2 hours. The mixture was concentrated in vacuo and the residue washed with diethyl ether (25 mL) four times. The product was a beige solid and was dried in vacuo to give 5.57 g, and about 100% yield. Results: HPLC purity: >99%. ¹H NMR (CDCl₃, δ): 1.52 (bq, 3H), 1.95 (bt, 6H), 7.57 (m, 27H), 7.74 (m, 18H).

### Comparative Formulation Example 1

A tetrapolymer of EAdMA/ECPMA/HAdA/a-GBLMA 15/15/30/40 was formulated with triphenylsulfonium nonaflate PAG (83 μmol/g of polymer), photodecomposable base triphenylsulfonium acetate (TPSA, 60 μmol/g of polymer) and 120 ppm 3M surfactant FC4430 were all dissolved to 3 wt % solids in a 80/19.5/0.5 mixture of MHIB/PGME/PGMEA solvents.

### Formulation Example 2

A tetrapolymer of EAdMA/ECPMA/HAdA/a-GBLMA 15/15/30/40 was formulated with triphenylsulfonium nonaflate PAG (83 μmol/g of polymer), photodecomposable base bis-triphenylsulfonium succinate (30 μmol/g of polymer) and 120 ppm 3M surfactant FC4430, were all dissolved to 3 wt % solids in a 80/19.5/0.5 mixture of MHIB/PGME/PGMEA solvents.

### Formulation Example 3

A tetrapolymer of EAdMA/ECPMA/HAdA/a-GBLMA 15/15/30/40 was formulated with triphenylsulfonium nonaflate PAG (83 μmol/g of polymer), photodecomposable base bis-triphenylsulfonium adamantane-1,3-dicarboxylate (30 μmol/g of polymer) and 120 ppm 3M surfactant FC4430, were all dissolved to 3 wt % solids in a 80/19.5/0.5 mixture of MHIB/PGME/PGMEA solvents.

### Formulation Example 4

A tetrapolymer of EAdMA/ECPMA/HAdA/a-GBLMA 15/15/30/40 was formulated with triphenylsulfonium nonaflate PAG (83 μmol/g of polymer), photodecomposable base triphenylsulfonium cyclohexanecarboxylate (60 μmol/g of polymer) and 120 ppm 3M surfactant FC4430, were all dissolved to 3 wt % solids in a 80/19.5/0.5 mixture of MHIB/PGME/PGMEA solvents.

### Formulation Example 5

A tetrapolymer of EAdMA/ECPMA/HAdA/a-GBLMA 15/15/30/40 was formulated with triphenylsulfonium nonaflate PAG (83 μmol/g of polymer), photodecomposable base bis-triphenylsulfonium cyclohexane-1,3-dicarboxylate (30 μmol/g of polymer) and 120 ppm 3M surfactant FC4430, were all dissolved to 3 wt % solids in a 80/19.5/0.5 mixture of MHIB/PGME/PGMEA solvents.

### Formulation Example 6

A tetrapolymer of EAdMA/ECPMA/HAdA/a-GBLMA 15/15/30/40 was formulated with triphenylsulfonium nonaflate PAG (83 μmol/g of polymer), photodecomposable base tris-triphenylsulfonium cyclohexane-1,3,5-tricarboxylate (20 μmol/g of polymer) and 120 ppm 3M surfactant FC4430, were all dissolved to 3 wt % solids in a 80/19.5/0.5 mixture of MHIB/PGME/PGMEA solvents.

### Comparative Formulation Example 7

A tetrapolymer of EAdMA/ECPMA/HAdA/a-GBLMA 15/15/30/40 was formulated with triphenylsulfonium tris[(trifluoromethyl)sulfonyl]methane PAG (83 μmol/g of polymer), photodecomposable base triphenylsulfonium acetate (TPSA, 60 μmol/g of polymer) and 120 ppm 3M surfactant FC4430, and all were dissolved to 3 wt % solids in a 80/19.5/0.5 mixture of MHIB/PGME/PGMEA solvents.

### Formulation Example 8

A tetrapolymer of EAdMA/ECPMA/HAdA/a-GBLMA 15/15/30/40 was formulated with triphenylsulfonium tris[(trifluoromethyl)sulfonyl]methane PAG (83 μmol/g of polymer), photodecomposable base bis-triphenylsulfonium succinate (30 μmol/g of polymer) and 120 ppm 3M surfactant FC4430, and all were dissolved to 3 wt % in an 80/19.5/0.5 mixture of MHIB/PGME/PGMEA solvents.

### Formulation Example 9

A tetrapolymer of EAdMA/ECPMA/HAdA/a-GBLMA 15/15/30/40 was formulated with triphenylsulfonium tris[(trifluoromethyl)sulfonyl]methane PAG (83 μmol/g of polymer), photodecomposable base bis-triphenylsulfonium adamantane-1,3-dicarboxylate (30 μmol/g of polymer) and with 120 ppm 3M surfactant FC4430, and all were dissolved to 3 wt % in a 801/19.5/0.5 mixture of MHIB/PGME/PGMEA solvents.

### Formulation Example 10

A tetrapolymer of EAdMA/ECPMA/HAdA/a-GBLMA 15/15/30/40 was formulated with triphenylsulfonium tris[(trifluoromethyl)sulfonyl]methane PAG (83 μmol/g of polymer), photodecomposable base triphenylsulfonium cyclohexanecarboxylate (60 μmol/g of polymer) and all were with 120 ppm 3M surfactant FC4430, all was dissolved to 3 wt % in a 80/19.5/0.5 mixture of MHIB/PGME/PGMEA solvents.

### Formulation Example 11

A tetrapolymer of EAdMA/ECPMA/HAdA/a-GBLMA 15/15/30/40 was formulated with triphenylsulfonium tris[(trifluoromethyl)sulfonyl]methane PAG (83 μmol/g of polymer), photodecomposable base bis-triphenylsulfonium cyclohexane-1,3-dicarboxylate (30 μmol/g of polymer) and 120 ppm 3M surfactant FC4430, and all were dissolved to 3 wt % in a 80/19.5/0.5 mixture of MHIB/PGME/PGMEA solvents.

### Formulation Example 12

A tetrapolymer of EAdMA/ECPMA/HAdA/a-GBLMA 15/15/30/40 was formulated with triphenylsulfonium tris[(trifluoromethyl)sulfonyl]methane PAG (83 μmol/g of polymer), photodecomposable base tris-triphenylsulfonium cyclohexane-1,3,5-tricarboxylate (20 μmol/g of polymer) and 120 ppm 3M surfactant FC4430, and all were dissolved to 3 wt % in a 80/19.5/0.5 mixture of MHIB/PGME/PGMEA solvents.

### Lithographic Example 13

Lithographic evaluation at 193 nm exposure was perform by spin-casting each photoresist on a silicon wafer pre-coated with 37 nm of AZ® 1C5D BARC (available from AZ® Electronic Materials Corps USA, 70 Meister Avenue, Somerville, N.J.). After spin casting, the film was soft-baked at 85° C. for 60s. After exposure using 193 nm wavelength through a 6% attenuated phase-sift mask at 0.85NA, the film was baked at 90° C. for 60 s and developed using AZ® 300MIF Developer (available from AZ® Electronic Materials Corps USA, 70 Meister Avenue, Somerville, N.J.). The dose to size 70 nm (1:1) trenches was recorded, and depth-of-focus and LWR (averaged through +/−0.10 um focus) were recorded at this dose. The Data is presented in Table 1.

TABLE 1

| Formulation # | PAG | Base or PDB | EL | Dose | DoF | LWR |
|---|---|---|---|---|---|---|
| 1 | TPS-Nf | TPSA | 12.8% | 46.3 | 0.325 | 5.77 |
| 2 | TPS-Nf | bTPSS | 13.5% | 42.8 | 0.325 | 6.32 |
| 3 | TPS-Nf | bTPSAdDC | 12.7% | 40.2 | 0.350 | 6.34 |
| 4 | TPS-Nf | TPScHC | 12.4% | 40.5 | 0.375 | 6.20 |
| 5 | TPS-Nf | bTPScHDC | 12.8% | 53.6 | 0.350 | 5.89 |
| 6 | TPS-Nf | tTPScHTC | 12.0% | 51.7 | 0.300 | 6.42 |
| 7 | TPS-CC1 | TPSA | 15.6% | 46.1 | 0.400 | 5.51 |
| 8 | TPS-CC1 | bTPSS | 16.6% | 42.9 | 0.325 | 6.32 |
| 9 | TPS-CC1 | bTPSAdDC | 17.2% | 40.1 | 0.300 | 6.42 |
| 10 | TPS-CC1 | TPScHC | 16.5% | 41.5 | 0.300 | 6.22 |
| 11 | TPS-CC1 | bTPScHDC | 16.4% | 56.4 | 0.325 | 5.78 |
| 12 | TPS-CC1 | tTPScHTC | 16.1% | 53.6 | 0.325 | 6.08 |

PAG: photoacid generator,
PBD: photodecomposable base,
EL: exposure latitude
DoF: depth of focus,
LWR: line width roughness

The inventive multifunctional photobase generators show good lithographic performance, and often better lithographic performance than the monofunctional photobase generator but require lower concentrations than the monofunctional (i.e. where x=0) to achieve similar diffusion efficacy.

1. A photosensitive composition sensitive to exposure radiation comprising a) an organic polymer b) a photobase generator of structure (1), and c) optionally a photoacid generator
(⁺A₁⁻O₂C)—B—(CO₂⁻A₂⁺)ₓ (1)
where A₁⁺ and A₂⁺ are independently an onium cation, x is greater than or equal to 1, and B is a nonfluorinated organic moiety.

2. The composition of claim 1, where the onium cation is selected from iodonium, sulfonium and ammonium cation.

3. The composition of claim 1, where the photobase generator has a pKa in the range of about −3 to 5.

4. The composition of claim 1, where in the photobase generator, x is in the range of 1-3.

5. The composition of claim 1, where A₁⁺ and A₂⁺ comprise at least one aromatic group.

6. The composition of claim 1, where B is free of —SO₃ moiety.

7. The composition of claim 1, where B in the photobase generator is selected from a moiety which is aromatic, aliphatic, heteroaromatic, heteroaliphatic and mixtures thereof.

8. The composition of claim 1, where the photoacid generator produces a strong acid.

9. The composition of claim 1, where the polymer is alkali insoluble and comprises an acid labile group.

10. The composition of claim 1, where the polymer is alkali soluble.

11. The composition of claim 10, where the photoresist further comprises a dissolution inhibitor.

12. The composition of claim 1, where the photobase generator is absorbing at the exposure radiation.

13. The composition of claim 1, where the polymer further comprises a chromophore.

14. The composition of claim 13, further comprising a crosslinker.

15. The composition of claim 14, further comprising a thermal acid generator.

16. A process for manufacturing a microelectronic device, comprising:
a) coating a substrate with a layer of composition of claim 1,
c) imagewise exposing the layer with exposure radiation;
d) optionally, post exposure baking the photoresist layer,
d) developing the photoresist layer with an aqueous alkaline developer.

17. The process of claim 16, where the exposure radiation is in the range of about 13 nm to about 300 nm.

18. The process of claim 16, the developer comprises tetramethyl ammonium hydroxide.

19. A process for manufacturing a microelectronic device, comprising;
a) coating a substrate with a layer of composition of claim 1 to form a underlayer,
b) coating a layer of photoresist over the underlayer;
c) imagewise exposing the layer(s) with exposure radiation;
e) optionally, post exposure baking the layer(s),
d) developing the layer(s) with an aqueous alkaline developer.

20. The process of claim 19, where the underlayer and the photoresist layer are developed in the same step.
